(19) United States
(12) Patent Application Publication
(10) Pub. No.: US 2026/0164593 A1
(43) Pub. Date: Jun. 11, 2026

(54) SERVER RACK WITH RACK RETURN CURRENT MITIGATION

(71) Applicant: Dell Products L.P., Round Rock, TX (US)

(72) Inventors: Douglas Evan Messick, Austin, TX (US); John Erven Jenne, Georgetown, TX (US); Corey Dean Hartman, Hutto, TX (US)

(21) Appl. No.: 18/976,885

(22) Filed: Dec. 11, 2024

(51) Int. Cl. H05K 7/14

(52) U.S. Cl. CPC H05K 7/1492; H05K 7/1489

(57) ABSTRACT

A server rack, including a plurality of rack units extending between a first side and a second side of the server rack, the first side opposite to the second side; a bus bar spanning the server rack and electrically coupled to each of the rack units and configured to provide power at each of the plurality of rack units, the bus bar positioned at a back side of the server rack, the back side between the first side and the second side; a cross-brace positioned at the back side of the server rack and extending between the first side and the second side of the server rack; and a ground connection coupled between the cross-brace and the bus bar, the ground connection configured to provide a low impedance connection for rack return current to the bus bar.

### BACKGROUND

### Field of the Disclosure

The disclosure relates generally to a server rack with rack return current mitigation.

### Description of the Related Art

As the value and use of information continues to increase, individuals and businesses seek additional ways to process and store information. One option available to users is information handling systems. An information handling system generally processes, compiles, stores, and/or communicates information or data for business, personal, or other purposes, thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

Server rack return current is the electrical current that flows back to the power source after passing through the server components. When this current inadvertently travels through the metal frame of the rack, it can create several problems. One major issue is electromagnetic interference (EMI), which can disrupt the performance of nearby electronic devices and degrade the quality of data transmission. Additionally, the flow of return current through the metal frame can lead to overheating, posing a risk of damage to the server components and potentially causing system failure.

### SUMMARY

Innovative aspects of the subject matter described in this specification may be embodied in a server rack including plurality of rack units extending between a first side and a second side of the server rack, the first side opposite to the second side; a bus bar spanning the server rack and electrically coupled to each of the rack units and configured to provide power at each of the plurality of rack units, the bus bar positioned at a back side of the server rack, the back side between the first side and the second side; a cross-brace positioned at the back side of the server rack and extending between the first side and the second side of the server rack; and a ground connection coupled between the cross-brace and the bus bar, the ground connection configured to provide a low impedance connection for rack return current to the bus bar.

Other embodiments of these aspects include corresponding systems and apparatus.

These and other embodiments may each optionally include one or more of the following features. For instance, the cross-brace is configured to provide structural integrity to the server rack. A plurality of servers each positioned within a respective rack unit of the plurality of rack units. A plurality of power shelves positioned with a respective rack unit of the plurality of rack units. An additional cross-brace positioned at the back side of the server rack and extending between the first side and the second side of the server rack; and an additional ground connection coupled between the additional cross-brace and the bus bar, the additional ground connection configured to provide an additional low impedance connection for rack return current to the bus bar. The cross-brace is physically coupled to the first side and the second side of the server rack. A structural shell surrounding a subset of the plurality of rack units, wherein the cross-brace is coupled to the structural shell.

The details of one or more embodiments of the subject matter described in this specification are set forth in the accompanying drawings and the description below. Other potential features, aspects, and advantages of the subject matter will become apparent from the description, the drawings, and the claims.

### BRIEF DESCRIPTION OF DRAWINGS

FIG. 1 is a block diagram of selected elements of an embodiment of an information handling system.

FIG. 2 illustrates a front view of a server rack.

FIG. 3 illustrates a perspective view of the server rack.

FIG. 4 illustrates a top-down view of a portion of the server rack.

FIG. 5 illustrates a zoomed in view of a portion of the server rack.

### DESCRIPTION OF PARTICULAR EMBODIMENT(S)

This disclosure discusses a server rack. In short, a low impedance connection can be established between the server rack and a bus bar (bus bar ground return) through a cross-brace for rack return current, described further herein.

Specifically, this disclosure discusses a server rack including a plurality of rack units extending between a first side and a second side of the server rack, the first side opposite to the second side; a plurality of servers each positioned within a respective rack unit of a first subset of the plurality of rack units; a first plurality of power shelves positioned within a respective rack unit of a second subset of the plurality of rack units; a second plurality of power shelves positioned within a respective rack unit of a third subset of the plurality of rack units; a bus bar spanning the server rack and electrically coupled to each of the rack units and configured to provide power from one or more of the plurality of power shelves to the servers at each of the first subset of the plurality of rack units, the bus bar positioned at a back side of the server rack, the back side between the first side and the second side; a first cross-brace positioned at the back side of the server rack and extending between the first side and the second side of the server rack, the cross-brace positioned between the first subset and the second subset of the plurality of rack units; a first ground connection coupled between the first cross-brace and the bus bar, the ground connection configured to provide a first low impedance connection for rack return current to the bus bar; a second cross-brace positioned at the back side of the server rack and extending between the first side and the second side of the server rack, the cross-brace positioned between the first subset and the third subset of the plurality of rack units; and a second ground connection coupled between the second cross-brace and the bus bar, the ground connection configured to provide a second low impedance connection for rack return current to the bus bar.

In the following description, details are set forth by way of example to facilitate discussion of the disclosed subject matter. It should be apparent to a person of ordinary skill in the field, however, that the disclosed embodiments are exemplary and not exhaustive of all possible embodiments.

For the purposes of this disclosure, an information handling system may include an instrumentality or aggregate of instrumentalities operable to compute, classify, process, transmit, receive, retrieve, originate, switch, store, display, manifest, detect, record, reproduce, handle, or utilize various forms of information, intelligence, or data for business, scientific, control, entertainment, or other purposes. For example, an information handling system may be a personal computer, a PDA, a consumer electronic device, a network storage device, or another suitable device and may vary in size, shape, performance, functionality, and price. The information handling system may include memory, one or more processing resources such as a central processing unit (CPU) or hardware or software control logic. Additional components of the information handling system may include one or more storage devices, one or more communications ports for communicating with external devices as well as various input and output (I/O) devices, such as a keyboard, a mouse, and a video display. The information handling system may also include one or more buses operable to transmit communication between the various hardware components.

For the purposes of this disclosure, computer-readable media may include an instrumentality or aggregation of instrumentalities that may retain data and/or instructions for a period of time. Computer-readable media may include, without limitation, storage media such as a direct access storage device (e.g., a hard disk drive or floppy disk), a sequential access storage device (e.g., a tape disk drive), compact disk, CD-ROM, DVD, random access memory (RAM), read-only memory (ROM), electrically erasable programmable read-only memory (EEPROM), and/or flash memory (SSD); as well as communications media such as wires, optical fibers, microwaves, radio waves, and other electromagnetic and/or optical carriers; and/or any combination of the foregoing.

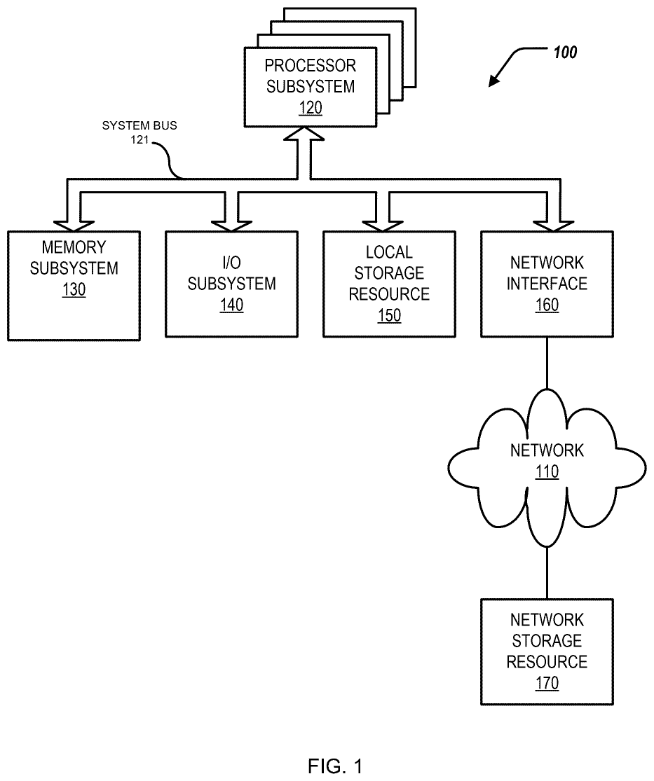

Particular embodiments are best understood by reference to FIGS. 1-5 wherein like numbers are used to indicate like and corresponding parts.

Turning now to the drawings, FIG. 1 illustrates a block diagram depicting selected elements of an information handling system 100 in accordance with some embodiments of the present disclosure. In various embodiments, information handling system 100 may represent different types of portable information handling systems, such as display devices, head mounted displays, head mount display systems, smart phones, tablet computers, notebook computers, media players, digital cameras, 2-in-1 tablet-laptop combination computers, and wireless organizers, or other types of portable information handling systems. In one or more embodiments, information handling system 100 may also represent other types of information handling systems, including desktop computers, server systems, controllers, and microcontroller units, among other types of information handling systems. Components of information handling system 100 may include, but are not limited to, a processor subsystem 120, which may comprise one or more processors, and system bus 121 that communicatively couples various system components to processor subsystem 120 including, for example, a memory subsystem 130, an I/O subsystem 140, a local storage resource 150, and a network interface 160. System bus 121 may represent a variety of suitable types of bus structures, e.g., a memory bus, a peripheral bus, or a local bus using various bus architectures in selected embodiments. For example, such architectures may include, but are not limited to, Micro Channel Architecture (MCA) bus, Industry Standard Architecture (ISA) bus, Enhanced ISA (EISA) bus, Peripheral Component Interconnect (PCI) bus, PCI-Express bus, HyperTransport (HT) bus, and Video Electronics Standards Association (VESA) local bus.

As depicted in FIG. 1, processor subsystem 120 may comprise a system, device, or apparatus operable to interpret and/or execute program instructions and/or process data, and may include one or more processing resources such as a central processing unit (CPU), microprocessor, microcontroller, digital signal processor (DSP), application specific integrated circuit (ASIC), or another digital or analog circuitry configured to interpret and/or execute program instructions and/or process data. In some embodiments, processor subsystem 120 may interpret and/or execute program instructions and/or process data stored locally (e.g., in memory subsystem 130 and/or another component of the information handling system). In the same or alternative embodiments, processor subsystem 120 may interpret and/or execute program instructions and/or process data stored remotely (e.g., in network storage resource 170).

Also in FIG. 1, memory subsystem 130 may comprise a system, device, or apparatus operable to retain and/or retrieve program instructions and/or data for a period of time (e.g., computer-readable media). Memory subsystem 130 may comprise random access memory (RAM), electrically erasable programmable read-only memory (EEPROM), a PCMCIA card, flash memory, magnetic storage, opto-magnetic storage, and/or a suitable selection and/or array of volatile or non-volatile memory that retains data after power to its associated information handling system, such as system 100, is powered down.

In information handling system 100, I/O subsystem 140 may comprise a system, device, or apparatus generally operable to receive and/or transmit data to/from/within information handling system 100. I/O subsystem 140 may represent, for example, a variety of communication interfaces, graphics interfaces, video interfaces, user input interfaces, and/or peripheral interfaces. In various embodiments, I/O subsystem 140 may be used to support various peripheral devices, such as a touch panel, a display adapter, a keyboard, an accelerometer, a touch pad, a gyroscope, an IR sensor, a microphone, a sensor, a camera, or another type of peripheral device.

Local storage resource 150 may comprise computer-readable media (e.g., hard disk drive, floppy disk drive, CD-ROM, and/or other types of rotating storage media, flash memory, EEPROM, and/or another type of solid state storage media) and may be generally operable to store instructions and/or data. Likewise, the network storage resource may comprise computer-readable media (e.g., hard disk drive, floppy disk drive, CD-ROM, and/or other types of rotating storage media, flash memory, EEPROM, and/or other types of solid state storage media) and may be generally operable to store instructions and/or data.

In FIG. 1, network interface 160 may be a suitable system, apparatus, or device operable to serve as an interface between information handling system 100 and a network 110. Network interface 160 may enable information handling system 100 to communicate over network 110 using a suitable transmission protocol and/or standard, including, but not limited to, transmission protocols and/or standards enumerated below with respect to the discussion of network 110. In some embodiments, network interface 160 may be communicatively coupled via network 110 to a network storage resource 170. Network 110 may be a public network or a private (e.g., corporate) network. The network may be implemented as, or may be a part of, a storage area network (SAN), a personal area network (PAN), a local area network (LAN), a metropolitan area network (MAN), a wide area network (WAN), a wireless local area network (WLAN), a virtual private network (VPN), an intranet, the Internet or another appropriate architecture or system that facilitates the communication of signals, data and/or messages (generally referred to as data). Network interface 160 may enable wired and/or wireless communications (e.g., NFC or Bluetooth) to and/or from information handling system 100.

In particular embodiments, network 110 may include one or more routers for routing data between client information handling systems 100 and server information handling systems 100. A device (e.g., a client information handling system 100 or a server information handling system 100) on network 110 may be addressed by a corresponding network address including, for example, an Internet protocol (IP) address, an Internet name, a Windows Internet name service (WINS) name, a domain name or other system name. In particular embodiments, network 110 may include one or more logical groupings of network devices such as, for example, one or more sites (e.g., customer sites) or subnets. As an example, a corporate network may include potentially thousands of offices or branches, each with its own subnet (or multiple subnets) having many devices. One or more client information handling systems 100 may communicate with one or more server information handling systems 100 via any suitable connection including, for example, a modem connection, a LAN connection including the Ethernet, or a broadband WAN connection including DSL, Cable, Ti, T3, Fiber Optics, Wi-Fi, or a mobile network connection including GSM, GPRS, 3G, or WiMax.

Network 110 may transmit data using a desired storage and/or communication protocol, including, but not limited to, Fibre Channel, Frame Relay, Asynchronous Transfer Mode (ATM), Internet protocol (IP), other packet-based protocol, small computer system interface (SCSI), Internet SCSI (iSCSI), Serial Attached SCSI (SAS) or another transport that operates with the SCSI protocol, advanced technology attachment (ATA), serial ATA (SATA), advanced technology attachment packet interface (ATAPI), serial storage architecture (SSA), integrated drive electronics (IDE), and/or any combination thereof. Network 110 and its various components may be implemented using hardware, software, or any combination thereof.

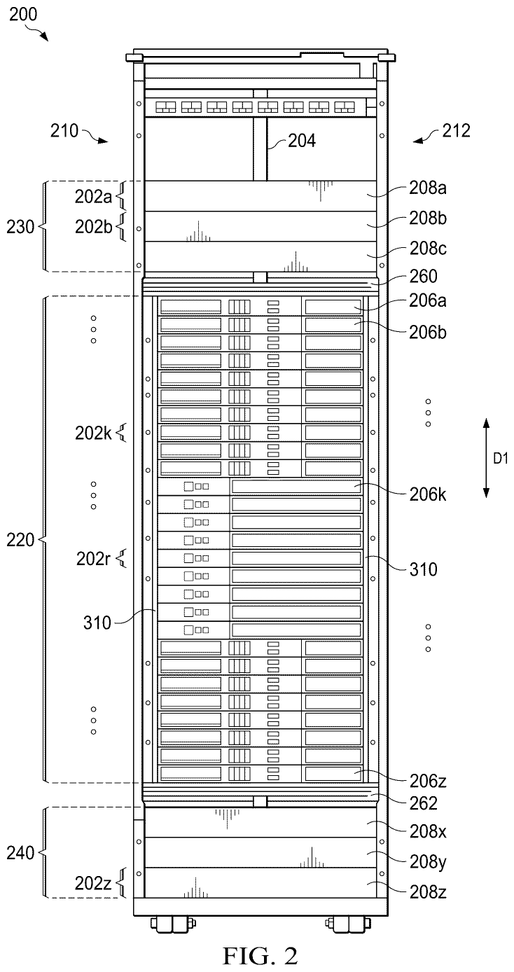

Turning to FIG. 2, FIG. 2 illustrates a server rack 200. The server rack 200 can include rack units 202a-202z (collectively referred to as rack units 202), a bus bar 204, servers 206a-206z (collectively referred to as servers 206), and power shelves 208a-208z (collectively referred to as power shelves 208). In some examples, the servers 206 are similar to, or include, the information handling system 100 of FIG. 1.

The server rack 200 includes a first side 210 and a second side 212. The first side is positioned opposite to the second side 212. The rack units 202 can extend between the first side 210 and the second side 212 of the server rack 200. The server rack 200 can include any number of rack units 202 depending on the application desired.

The servers 206 can be positioned within a respective rack unit 202. Specifically, the servers 206 can be positioned within a respective rack unit 202 of a first subset 220 of the rack units 202. In other words, the servers 206 can be coupled to respective rack units 202 of the first subset 220 of the rack units 202. The server rack 200 can include any number of servers 206 depending on application desired.

The power shelves 208 can be positioned within a respective rack unit 202. Specifically, the power shelves 208a-208c can be positioned within a respective rack unit 202 of a second subset 230 of the rack units 202. In other words, the power shelves 208a-208c can be coupled to respective rack units 202 of the second subset 230 of the rack units 202. Furthermore, the power shelves 208x-208z can be positioned within a respective rack unit 202 of a third subset 240 of the rack units 202. In other words, the power shelves 208x-208z can be coupled to respective rack units 202 of the third subset 240 of the rack units 202. The server rack 200 can include any number of power shelves 208 depending on the application desired.

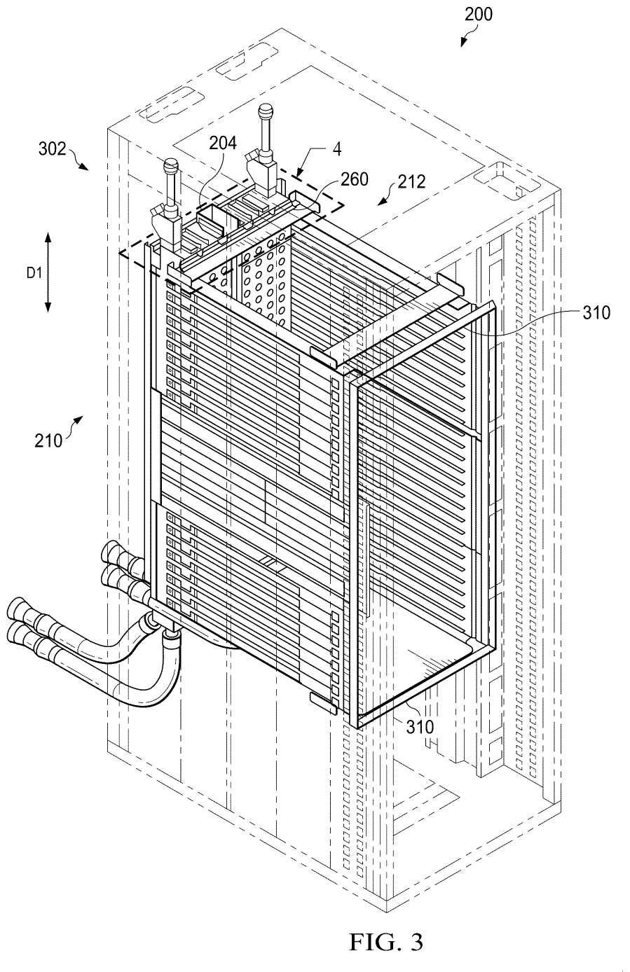

FIG. 3 illustrates a perspective view of the server rack 200. For simplicity of illustration, the server rack 200 is shown without the inclusion of the servers 206 and the power shelves 208. Referring to FIGS. 2 and 3, the server rack 200 includes the bus bar 204. The bus bar 204 is positioned at a back side 302 of the server rack 200. The back side 302 is positioned between the first side 210 and the second side 212 of the server rack 200. The bus bar 204 spans at least a portion of the server rack 200 along the direction D1. In some examples, the bus bar 204 is electrically coupled to one or more of the rack units 202. In some examples, the bus bar 204 is electrically couped to each of the rack units 202. The bus bar 204 is configured to provide power from one or more of the power shelves 208 to one or more of servers 206 at the first subset 220 of rack units 202.

In some examples, the server rack 200 can include a structural shell 310. The structural shell 310 can surround the first subset 220 of rack units 202.

In short, a low impedance connection can be established between the server rack 200 and the bus bar 204 (bus bar ground return) through a cross-brace for rack return current, described further herein.

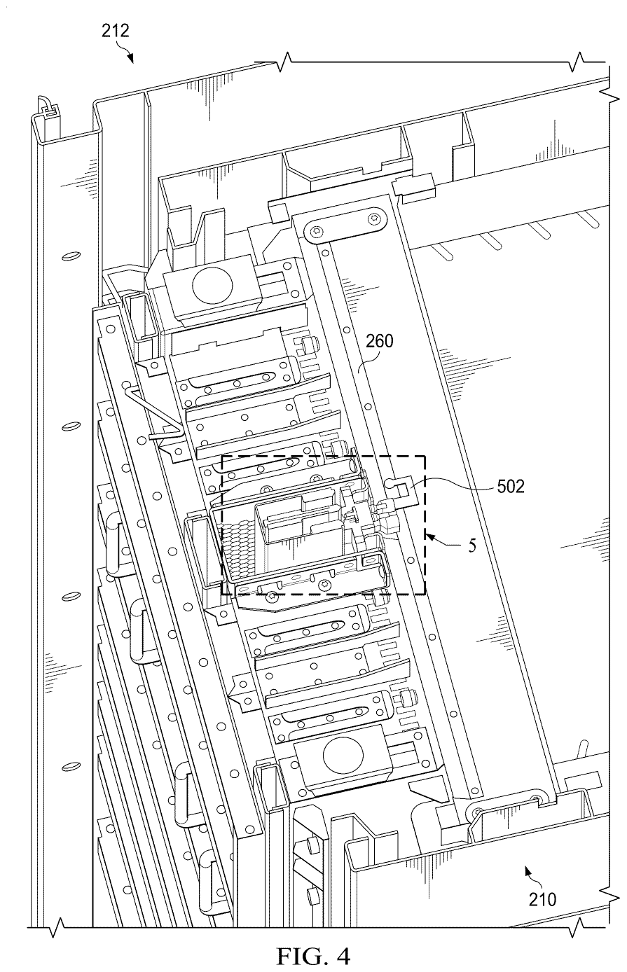

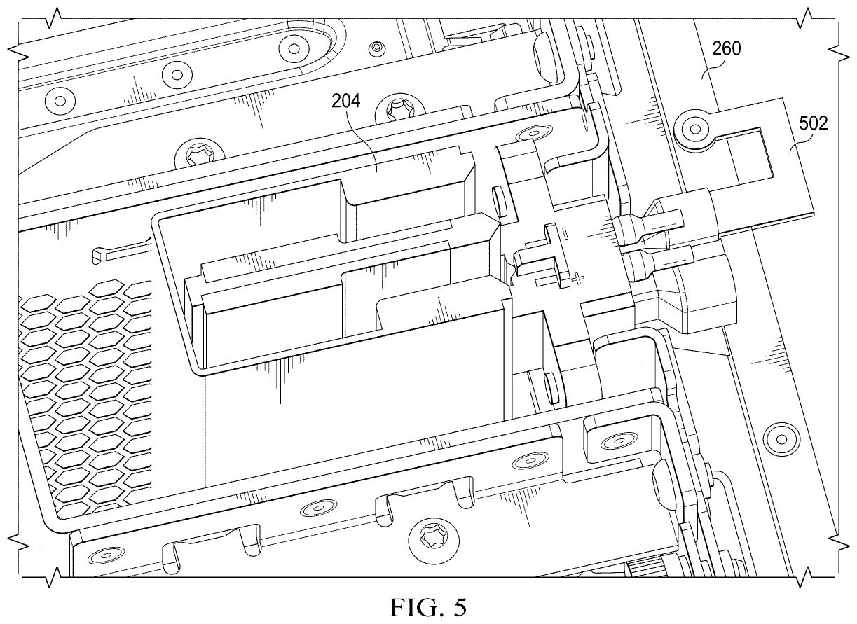

FIG. 4 illustrates a top-down view of a portion of the server rack 200; and FIG. 5 illustrates a zoomed in view of the portion of the server rack 200. Referring to FIGS. 2-5, the server rack 200 includes a first cross-brace 260. The first cross-brace 260 is positioned between the first side 210 and the second side 212 of the server rack 200. The first cross-brace 260 is positioned between the first subset 220 of rack units 202 and the second subset 230 of rack units 202. Specifically, the first cross-brace 260 is positioned between the power shelves 208a-208c and the servers 206. The first cross-brace 260 is configured to provide structural integrity to the server rack 200. In some examples, the first cross-brace 260 is physically coupled to the first side 210 and the second side 212 of the server rack 200. In some examples, the first cross-brace 260 is coupled to the structural shell 310. In some examples, the first cross-brace 260 is formed of a metal, or metal-based material. In some examples, the first cross-brace 260 is electrically conductive.

The server rack 200 can include a first ground connection 502. The first ground connection 502 can be coupled between the first cross-brace 260 and the bus bar 204. The first ground connection 502 is configured to provide a first low impedance connection for rack return current to the bus bar 204. Specifically, the first ground connection 502 can include a wire (e.g., of a gauge to sync the rack return current to the bus bar 204). That is, the first ground connection 502 is a low impedance connection that provides a path of least resistance for the rack return current that can travel from the rack to the bus bar 204 through the first ground connection 502. That is, the combination of the first cross-brace 260 and the first ground connection 502 can form an integrated dedicated busbar ground connection path to create a path for rack return current back to the bus bar 204. That is, the first cross-brace 260 has the lowest impedance path for stray rack current to travel to the busbar 204 (busbar ground 204) through the first ground connection 502.

In some examples, the server rack 200 includes a second cross-brace 262. The second cross-brace 262 is positioned between the first side 210 and the second side 212 of the server rack 200. The second cross-brace 262 is positioned between the first subset 220 of rack units 202 and the third subset 240 of rack units 202. Specifically, the second cross-brace 260 is positioned between the power shelves 208x-208z and the servers 206. The second cross-brace 262 is configured to provide structural integrity to the server rack 200. In some examples, the second cross-brace 262 is physically coupled to the first side 210 and the second side 212 of the server rack 200. In some examples, the second cross-brace 262 is coupled to the structural shell 310. In some examples, the second cross-brace 262 is formed of a metal, or metal-based material. In some examples, the second cross-brace 262 is electrically conductive.

The server rack 200 can include a second ground connection, similar to the first ground connection 502. The second ground connection can be coupled between the second cross-brace 262 and the bus bar 204. The second ground connection is configured to provide a second low impedance connection for rack return current to the bus bar 204. Specifically, the second ground connection can include a wire (e.g., of a gauge to sync the rack return current to the bus bar 204). That is, the second ground connection is a low impedance connection that provides a path of least resistance for the rack return current that can travel from the rack to the bus bar 204 through the second ground connection. That is, the combination of the second cross-brace 262 and the second ground connection can form an integrated dedicated busbar ground connection path to create a path for rack return current back to the bus bar 204. That is, the second cross-brace 262 has the lowest impedance path for stray rack current to travel to the busbar 204 (busbar ground 204) through the second ground connection.

In some examples, the combination of i) the first cross-brace 260 and the first ground connection 502 and ii) the second cross-brace 262 and the second ground connection can form multiple integrated dedicated busbar ground connection paths to create multiple paths for rack return current back to the bus bar 204. That is, the combination of i) the first cross-brace 260 and the first ground connection 502 and ii) the second cross-brace 262 and the second ground connection both have the lowest impedance path for stray rack current to travel to the bus bar 204 (busbar ground 204) through the first ground connection 502 and/or the second ground connection. That is, the stray rack current can return to the bus bar 204 through the first ground connection 502 and the first cross-brace 260 and/or the second ground connection and the second cross-brace 262.

In some examples, the server rack 200 can include any number of cross-braces and any number of corresponding ground connections.

The above disclosed subject matter is to be considered illustrative, and not restrictive, and the appended claims are intended to cover all such modifications, enhancements, and other embodiments which fall within the true spirit and scope of the present disclosure. Thus, to the maximum extent allowed by law, the scope of the present disclosure is to be determined by the broadest permissible interpretation of the following claims and their equivalents, and shall not be restricted or limited by the foregoing detailed description.

Herein, “or” is inclusive and not exclusive, unless expressly indicated otherwise or indicated otherwise by context. Therefore, herein, “A or B” means “A, B, or both,” unless expressly indicated otherwise or indicated otherwise by context. Moreover, “and” is both joint and several, unless expressly indicated otherwise or indicated otherwise by context. Therefore, herein, “A and B” means “A and B, jointly or severally,” unless expressly indicated otherwise or indicated otherwise by context.

The scope of this disclosure encompasses all changes, substitutions, variations, alterations, and modifications to the example embodiments described or illustrated herein that a person having ordinary skill in the art would comprehend. The scope of this disclosure is not limited to the example embodiments described or illustrated herein. Moreover, although this disclosure describes and illustrates respective embodiments herein as including particular components, elements, features, functions, operations, or steps, any of these embodiments may include any combination or permutation of any of the components, elements, features, functions, operations, or steps described or illustrated anywhere herein that a person having ordinary skill in the art would comprehend. Furthermore, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative.

What is claimed is:

1. A server rack, including:
a plurality of rack units extending between a first side and a second side of the server rack, the first side opposite to the second side;
a bus bar spanning the server rack and electrically coupled to each of the rack units and configured to provide power at each of the plurality of rack units, the bus bar positioned at a back side of the server rack, the back side between the first side and the second side;
a cross-brace positioned at the back side of the server rack and extending between the first side and the second side of the server rack; and
a ground connection coupled between the cross-brace and the bus bar, the ground connection configured to provide a low impedance connection for rack return current to the bus bar.

2. The server rack of claim 1, wherein the cross-brace is configured to provide structural integrity to the server rack.

3. The server rack of claim 1, further including:
a plurality of servers each positioned within a respective rack unit of the plurality of rack units.

4. The server rack of claim 1, further including:
a plurality of power shelves positioned with a respective rack unit of the plurality of rack units.

5. The server rack of claim 1, further including:
an additional cross-brace positioned at the back side of the server rack and extending between the first side and the second side of the server rack; and
an additional ground connection coupled between the additional cross-brace and the bus bar, the additional ground connection configured to provide an additional low impedance connection for rack return current to the bus bar.

6. The server rack of claim 1, wherein the cross-brace is physically coupled to the first side and the second side of the server rack.

7. The server rack of claim 1, further including:
a structural shell surrounding a subset of the plurality of rack units,
wherein the cross-brace is coupled to the structural shell.

8. A server rack, including:
a plurality of rack units extending between a first side and a second side of the server rack, the first side opposite to the second side;
a plurality of servers each positioned within a respective rack unit of a first subset of the plurality of rack units;
a plurality of power shelves positioned within a respective rack unit of a second subset of the plurality of rack units;
a bus bar spanning the server rack and electrically coupled to each of the rack units and configured to provide power from one or more of the plurality of power shelves to the servers at each of the first subset of the plurality of rack units, the bus bar positioned at a back side of the server rack, the back side between the first side and the second side;
a cross-brace positioned at the back side of the server rack and extending between the first side and the second side of the server rack, the cross-brace positioned between the first subset and the second subset of the plurality of rack units; and
a ground connection coupled between the cross-brace and the bus bar, the ground connection configured to provide a low impedance connection for rack return current to the bus bar.

9. The server rack of claim 8, wherein the cross-brace is configured to provide structural integrity to the server rack.

10. The server rack of claim 8, further including:
an additional cross-brace positioned at the back side of the server rack and extending between the first side and the second side of the server rack; and
an additional ground connection coupled between the additional cross-brace and the bus bar, the additional ground connection configured to provide an additional low impedance connection for rack return current to the bus bar.

11. The server rack of claim 8, wherein the cross-brace is physically coupled to the first side and the second side of the server rack.

12. The server rack of claim 8, further including:
a structural shell surrounding the first subset of the plurality of rack units,
wherein the cross-brace is coupled to the structural shell.

13. A server rack, including:
a plurality of rack units extending between a first side and a second side of the server rack, the first side opposite to the second side;
a plurality of servers each positioned within a respective rack unit of a first subset of the plurality of rack units;
a first plurality of power shelves positioned within a respective rack unit of a second subset of the plurality of rack units;
a second plurality of power shelves positioned within a respective rack unit of a third subset of the plurality of rack units;
a bus bar spanning the server rack and electrically coupled to each of the rack units and configured to provide power from one or more of the plurality of power shelves to the servers at each of the first subset of the plurality of rack units, the bus bar positioned at a back side of the server rack, the back side between the first side and the second side;
a first cross-brace positioned at the back side of the server rack and extending between the first side and the second side of the server rack, the cross-brace positioned between the first subset and the second subset of the plurality of rack units;
a first ground connection coupled between the first cross-brace and the bus bar, the ground connection configured to provide a first low impedance connection for rack return current to the bus bar;
a second cross-brace positioned at the back side of the server rack and extending between the first side and the second side of the server rack, the cross-brace positioned between the first subset and the third subset of the plurality of rack units; and
a second ground connection coupled between the second cross-brace and the bus bar, the ground connection configured to provide a second low impedance connection for rack return current to the bus bar.

14. The server rack of claim 13, wherein the first and the second cross-brace are configured to provide structural integrity to the server rack.

15. The server rack of claim 13, wherein the first and the second cross-brace are physically coupled to the first side and the second side of the server rack.

16. The server rack of claim 13, further including:
a structural shell surrounding the first subset of the plurality of rack units,
wherein the first and the second cross-brace are coupled to the structural shell.
